(19) United States
(12) Patent Application Publication
(10) Pub. No.: US 2003/0142561 A1
(43) Pub. Date: Jul. 31, 2003

(54) Apparatus and caching method for optimizing server startup performance

(75) Inventors: Robert S. Mason JR., Uxbridge, MA (US); Brian L. Garrett, Hopkinton, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: I/O Integrity, Inc., Medway, MA

(21) Appl. No.: 10/319,198

(22) Filed: Dec. 13, 2002

Related U.S. Application Data
(60) Provisional application No. 60/340,656, filed on Dec. 14, 2001.

(51) Int. Cl. G11C 7/00

(52) U.S. Cl. 365/200

(57) ABSTRACT

An apparatus and method implemented in embedded software that provides instant startup functionality to host computers. The apparatus consists of an embedded controller with microprocessor and interface logic and a large amount of cache memory that is battery protected. The method detects data requested by the host during boot sequences, and saves that and associated meta-data in non-volatile memory. The boot process optimizer can then use this information on subsequent starts to provide the data from the faster cache memory instead of a relatively slower mechanically spinning hard disk drives or other mass memory devices. By utilizing locked in memory indicators, the boot data stored in cache memory will be preserved during subsequent accesses by post-boot operations of the host.

### RELATED APPLICATIONS

This application claims the benefit of U.S. Provisional Application No. 60/340,656, filed Dec. 14, 2001. The entire teachings of the above application are incorporated herein by reference.

### BACKGROUND OF THE INVENTION

This invention relates generally to the field of storage controllers, and more particularly to a plug and play apparatus that is cabled between a storage controller and one or more disk drives that are dedicated to improving performance of system start up.

Today computers have relatively fast processors, prodigious amounts of memory and seemingly endless hard disk space. But hard disk drives remain relatively slow or significant access time improvement has not been seen in many years. Drive capacity increases every year, performance becomes even more of a challenge. Indeed, magnetic disk performance has not kept pace with the Moore's Law trend in disk densities: disk capacity has increased nearly 6,000 times over the past four decades, while disk performance has increased only eight times.

Disk drive performance, which is limited by rotational latency and mechanical access delays, is measured in milliseconds while memory access speed is measured in microseconds. To improve system performance it is therefore desirable to decrease the number of disk accesses by keeping frequently referenced blocks of data in memory or by anticipating the blocks that will soon be accessed and pre-fetching them into memory. The practice of maintaining frequently accessed data in high-speed memory avoiding accesses to slower memory or media is called caching. Caching is now a feature of most disk drives and operating systems, and is often implemented in advanced disk controllers, as well.

Common caching techniques include Least Recently Used (LRU) replacement, anticipatory pre-fetch, and write through caching. LRU replacement comes about from realizing that read requests from a host computer resulting in a disk drive access are saved in cache memory in anticipation of the same data being accessed again in the near future. However, since a cache memory is finite in size, it is quickly filled with such read data. Once full, a method is needed whereby the least recently used data is retired from the cache and is replaced with the latest read data. This method is referred to as Least Recently Used replacement. Read accesses are often sequential in nature and various caching methods can be employed to detect such sequentiality in order to pre-fetch the next sequential blocks from storage into the cache so that subsequent sequential access may be service from fast memory. This caching method is referred to as anticipatory pre-fetch. Write data is often referenced shortly after being written to media. Write through caching is therefore employed to save the write data in cache as it is also written safely to storage to improve likely read accesses of that same data. Each of the above cache methods are employed with a goal of reducing disk media access and increasing memory accesses resulting in significant system performance improvement.

Performance benefits can also be realized with caching due to the predictable nature of disk I/O workloads. Most I/O's are reads instead of writes (typically about 80%) and those reads tend to have a high locality of reference, in the sense that reads that happen close to each other in time tend to come from regions of disk that are close to each other in physical proximity. Another predictable pattern is that reads to sequential blocks of a disk tend to be followed by still further sequential read accesses. This behavior can be recognized and optimized through pre-fetch as described earlier. Finally, data written is most likely read during a short period of time after it was written. The aforementioned I/O workload profile tendencies make for an environment in which the likelihood that data will be accessed from high speed cache memory is increasing thereby avoiding disk accesses.

Storage controllers range in size and complexity from a simple Peripheral Component Interconnect (PCI) based Integrated Device Electronics (IDE) adapter in a Personal Computer (PC) to a refrigerator-sized cabinet full of circuitry and disk drives. The primary responsibility of such a controller is to manage Input/Output (I/O) interface command and data traffic between a host Central Processing Unit (CPU) and disk devices. Advanced controllers typically additionally then add protection through mirroring and advanced disk striping techniques. Caching is almost always implemented in high-end RAID controllers to overcome a performance degradation known as the RAID-5 write penalty. The amount of cache memory available in low-end disk controllers is typically very small and relatively expensive compared to the subject invention. The target market for caching controllers is typically the SCSI or Fibre channel market which is more costly and out of reach of PC and low-end server users. Caching schemes as used in advanced high-end controllers are very expensive and typically beyond the means of entry level PC and server users.

Certain disk drive manufacturers add memory to a printed circuit board attached to the drive as a speed-matching buffer. Such buffers can be used to alleviate a problem that would otherwise occur as a result of the fact that data transfers to and from a disk drive are much slower than the I/O interface bus between the CPU and the drive. Drive manufacturers often implement caching in this memory. But the amount of this cache is severely limited by space and cost. Drive-vendor implemented caching algorithms are often unreliable or unpredictable so that system integrators and resellers will even disable drive write cache.

These drive- and controller-based architectures thus implement caching as a secondary function.

Solid State Disk (SSD) is a performance optimization technique implemented in hardware, but is different than hardware based caching. SSD is implemented by a device that appears as a disk drive, but is actually composed instead entirely of semiconductor memory. Read and write accesses to SSD therefore occur at electronic memory speeds. A battery and hard disk storage are typically provided to protect against data loss in the event of a power outage. The battery and disk device are configured “behind” the semiconductor memory to enable flushing of the contents of the SSD when power is lost.

The amount of memory in an SSD is equal in size to the drive capacity available to the user. In contrast, the size of a cache represents only a portion of the device (typically limited to the number of the “hot” data blocks that applications are expected to need). SSD is therefore very expensive compared to a caching implementation. SSD is typically used in highly specialized environments where a user knows exactly which data may benefit from high-speed memory speed access (e.g., a database paging device). Identifying such data sets that would benefit from an SSD implementation and migrating them to an SSD device is difficult and can become obsolete as workloads evolve over time.

Storage caching is sometimes implemented in software to augment operating system and file system level caching. Software caching implementations are very platform and operating system specific. Such software needs to reside at a relatively low level in the operating system or in file level hierarchy. Unfortunately, this leads to a likely source of resource conflicts, crash-inducing bugs, and possible sources of data corruption. New revisions of operating systems and applications necessitate renewed test and development efforts and possible data reliability issues. The memory allocated for caching by such implementations comes at the expense of the operating system and applications that need to use the very same system memory.

Microsoft with its ONNOW technology in Windows XP, and Intel with its Instantly Available PC (IAPC) technology, have each shown the need for improved start up or “boot” speeds. These solutions center around improving processor performance, hardware initialization and optimizing the amount and location of data that needs to be read from a disk drive. While these initiatives can provide significant improvement to start times, there is still a large portion of the start process depends upon disk performance. The problem with their so-called sleep/wake paradigm is that Microsoft needs application developers to change their code to be able to handle suspended communication and I/O services. From Microsoft's perspective, the heart of the initiative is a specification for development standards and Quality Assurance practices to ensure compliance. Thus, their goal is more to avoid application crashes and hangs during power mode transitions than to specifically improve the time it takes to do these transitions.

In general, therefore, drive performance is not keeping pace with performance advancements in processor, memory and bus technology. Controller based caching implementations are focused on the high end SCSI and Fiber Channel market and are offered only in conjunction with costly RAID data protection schemes. Solid State Disk implementations are still costly and require expertise to configure for optimal performance. The bulk of worldwide data storage sits on commodity IDE/ATA drives where storage controller based performance improvements have not been realized. System level performance degradation due to rising data consumption and reduced numbers of actuators per GB are expected to continue without further architectural advances.

### SUMMARY OF THE INVENTION

The present invention relates to a start up or “boot” process optimizer that runs on a mass storage device controller that provides for data caching during normal operation of the system. In a preferred embodiment, the boot process optimizer is implemented as an inline device connected between the host bus adapter or other connection to a host Central Processing Unit (CPU) and the mass storage device. The controller contains a non volatile memory cache, such as a semiconductor memory controlled by a battery backed up power source. This permits the stored boot data to remain available for access during subsequent boot processes, even when system power is removed.

The non-volatile cache memory has a faster access time than the mass storage device, so that the boot data is available to be read from the cache memory to decrease the execution time of a subsequent boot process. The boot process optimizer is careful to only use predetermined portions of the non-volatile cache memory for storing boot data, so that other regions of the cache memory are available for caching other host CPU requests for data from the mass storage device, subsequent to the boot processes.

In one embodiment, a usage counter is associated with portions of the cache memory to track boot data utilization. Each time that data requested by the host during a current boot matches data pre-stored in the non volatile cache memory, the usage counter is incremented. However, if data in the non volatile memory is found not to have been used during the current boot process, its usage counter is decremented by a predetermined factor. In this manner a fast decay function is provided for remembered boot data, so that data accessed during recent boots is given priority over less frequently used accesses.

The cache memory may have a number of cache slots, each cache slot containing one or more memory locations, and a Locked in Memory (LIM) flag associated with each cache slot. In this configuration, the LIM flag is used to determine if the respective slot is presently dedicated for storing boot data, or can be used for subsequent, post-boot caching.

The extents for boot data to be retained in non-volatile memory are determined from the parameters of the I/O requests made by the host CPU during an initial boot process. This permits the boot process optimizer to run independently of a host CPU operating system, and to store both operating system and application program data without knowledge of which is which.

In one embodiment, the boot process optimizer is implemented in a cache memory controller located in-line between the host CPU and the mass storage device. However, the boot process optimizer can also be implemented in an on-drive disk controller, in a host input/output bus adapter, within a cache memory controller located in the host CPU, or even in a CPU instruction cache.

The boot process optimizer can be used with any type of mass storage device, such as a disk drive, a tape drive, or semiconductor memory.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention. The above and further advantages of the invention may be better understood by referring to the accompanying drawings in which:

FIG. 1 is a top-level diagram for an apparatus for saving and restoring boot data.

FIG. 2 is a logical view of the hardware apparatus.

FIG. 3 is a flow chart of the boot process software method.

### DETAILED DESCRIPTION OF THE INVENTION

A description of preferred embodiments of the invention follows.

In a preferred embodiment, the boot process is implemented on a hardware platform which implements caching methods using embedded software. This hardware platform typically consists of a fast microprocessor (CPU), from about 256 MB to 4 GB or more of relatively fast memory, flash memory for saving embedded code and battery protected non-volatile memory for storing persistent information such as boot data. It also includes host I/O interface control circuitry for communication between disk drives or other mass storage devices and the CPU within a host platform. Other interface and/or control chips and memory may be used for development and testing of the product.

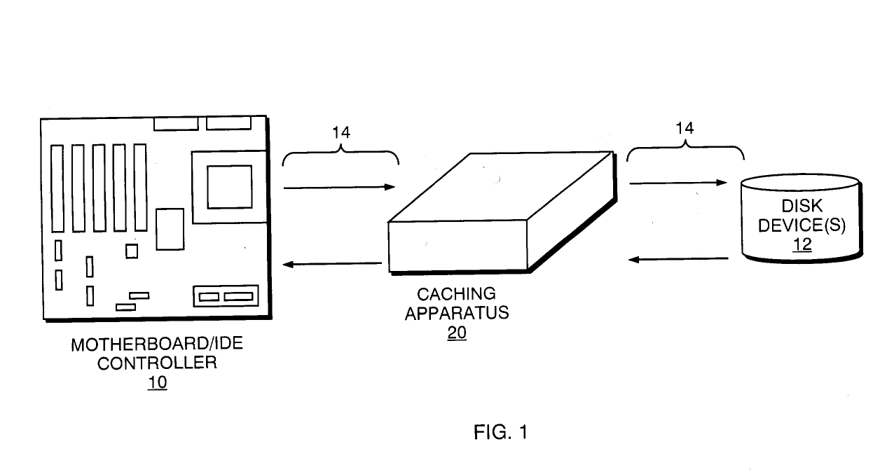

FIG. 1 is a high level diagram illustrating one such hardware platform. The associated host 10 may typically be a personal computer (PC) workstation or other host data processor. The host as illustrated is a PC motherboard, which includes an integrated device electronic (IDE) disk controller embedded within it. As is well known in the art, the host 10 communicates with mass storage devices such as disk drives 12 via a host bus adapter interface 14. In the illustrated embodiment the host bus adapter interface 14 is an Advanced Technology Attachment (ATA) compatible adapter; however, it should be understood that other host interfaces 14 are possible.

In this embodiment, the boot process is implemented on a hardware platform, referred to herein as a cache controller apparatus 20. This apparatus 20 performs caching functions for the system after the boot processing is complete, during normal states of operation. Thus, once boot processing is complete, disk accesses made by the host 10 are first processed by the cache controller 20. The cache controller 20 ensures that if any data requested previously from the disk 12 still resides in memory associated with the cache controller 20, then that request is served from the memory rather than retrieving the data from the disk 12.

The operation of the cache controller 20, including both the caching functions and the boot processing described herein in greater detail below, is transparent to both the host 10 and the disk 12. To the host 10, the cache controller 20 simply appears as an interface to the disk device 12. Likewise, to the disk device 12, the cache controller interface looks as the host 10 would.

In accordance with the present invention, the cache controller 20 also implements a boot process, for example, during a start up power on sequence. The boot process retrieves boot data from the memory rather than the disk 12 as much as possible. Data may also be predictably checked by the cache controller 20, thereby anticipating access as required by the host 10 prior to their actually being requested.

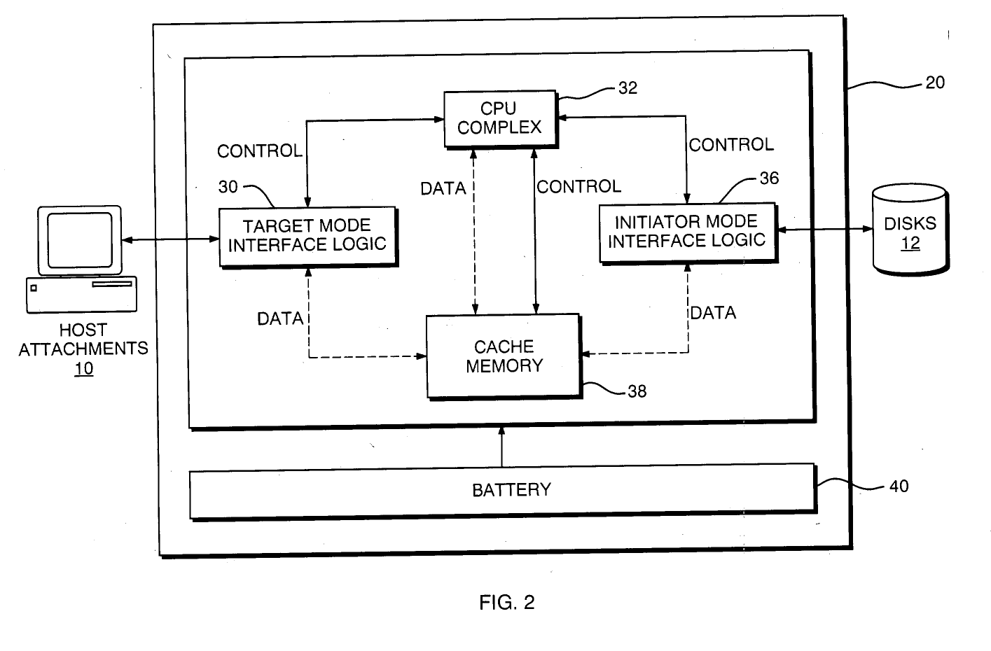

FIG. 2 depicts a logical view of the controller 20. Hosts 10 are attached to the target mode interface 30 on the left side of the diagram. This interface 30 is controlled via the CPU 32 and transfers data between the host 10 and the controller 20. The CPU 32 is responsible for executing the advanced caching algorithms and managing the target and initiator mode interface logic 36. The initiator mode interface logic 36 controls the flow of data between the apparatus 20 and the disk devices 12. It is also managed by the CPU 32. The cache memory 38 is a large amount of RAM that stores host, disk device, and meta data. The cache memory 38 can be thought of as including a number of cache “lines” or “slots”, each slot consisting of a predetermined number of memory locations. As will be understood shortly, each cache slot also has certain associated meta data and flags, including at least a usage counter and a Locked In Memory (LIM) flag.

A major differentiator in the controller 20 used for implementing this invention from a standard caching storage controller is that some, or all, of the memory used for caching user data is protected by a battery 40 in the case of a power loss. The integration of the battery 40 enables the functionality provided by the boot algorithms. The battery is capable of keeping the data for many days without system power.

In a preferred embodiment, a predetermined portion of the total available battery protected cache memory 38 space is reserved for boot data. A boot process running on the CPU 32, in an initial mode, determines that a system boot is in process and begins recording which data blocks or tracks are accessed from the disk 12. The accessed data is then not only provided to the host 10, but also then preserved in the non-volatile cache memory 38 for use during subsequent boot processing. As will be understood shortly, care is taken to mark the boot blocks stored in memory 38 so that they are not overwritten during post-boot, normal operation of the cache controller 20.

On subsequent start ups, even if power is removed from the system, when access to these same areas of the disk 12 is requested, they can therefore occur at electronic speeds for significantly faster performance.

The portion of cache 30 devoted to storing boot data can be anywhere from 10% or 50% of the available memory 38; the exact amount depends upon configuration settings of the application and the economics of the host system implementation. It should be understood that this proportion could be any other portion or variable size in other implementations.

If the reserved space for the user boot data is full, then the cache controller can optionally resort to the technique described in our co-pending U.S. Patent Application Serial Number B/C,C entitled “Apparatus and Meta Data Caching Method for Optimizing Server Startup Performance”, filed on the same date herewith. The contents of that application are hereby incorporated by reference in their entirety here. In accordance with a process described in that application, information about the data used during the boot process can be saved in a meta data list in non-volatile memory. Although this process uses less of the memory 38, and it is slower, the meta data can however still be used to retrieve the data from the disk drive before being requested by the host CPU thereby increasing startup performance.

As has been alluded to above, in addition to the extent lists saved in non-volatile memory, the actual user data from the boot process is preserved in cache memory 38 during further operation of the system, after the boot process is complete. To preserve this boot data while still providing normal cache functionality during post-boot I/O workloads, the LIM flag for each cache slot is used. This flag indicates that the data in that particular slot is boot data, and that it should remain locked in memory for the next boot process.

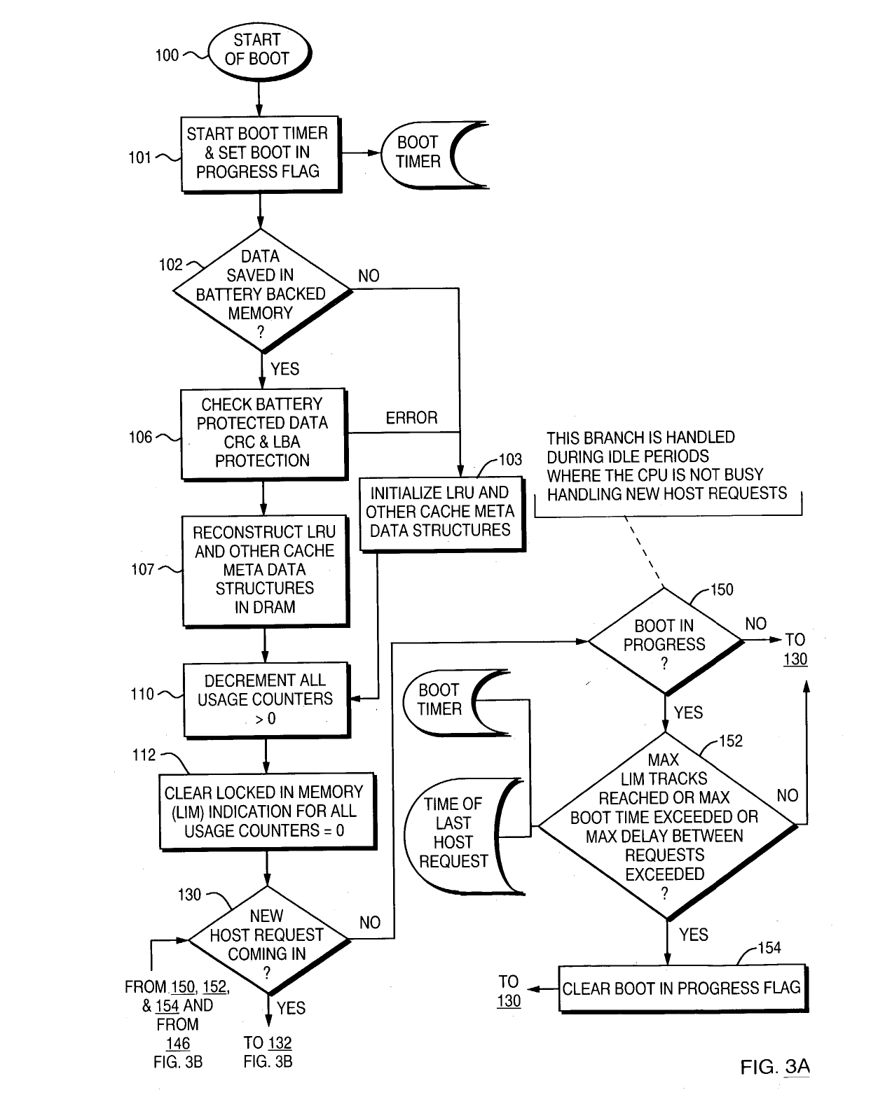

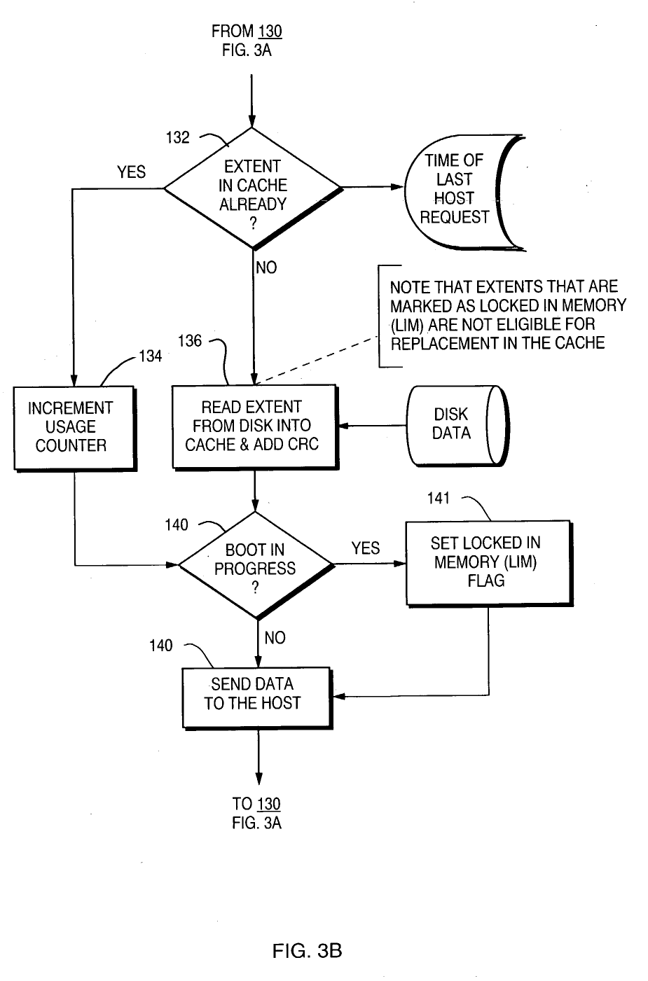

FIG. 3 is a flow diagram of a preferred embodiment of the boot process. Step 100 is entered upon detecting that the system is in a boot mode. This can be done, for example, by a circuit that detects the application of external power to the system. From 100, the cache controller 20 will at step 101 start a boot process timer and set a “boot in process” flag. In step 102, a flag previously stored in non-volatile memory is checked to determine if the battery backed up memory 38 contains saved data. If not, then state 103 is entered in which cache meta data structures, such as a Least Recently Used (LRU) list, are initialized. Other meta data maintained about the contents of memory 38 may include information such as the time of the last boot, number of cache slots reserved for boot data and the like.

If the meta data indicates there is preserved boot data in memory 38, the validity of the data will be tested in step 106 by checking the 32-bit CRC and LBA of each data block in step 108. Any data that fails the CRC and LBA checks will be discarded in step 107. Thus, in accordance with one preferred embodiment, the data written into the battery-backed memory by the host and the data read into cache memory from the disk drive(s) is protected by a 32-bit CRC word and a 32-bit LBA. This extra information is added by the controller 20 as the data is being received and stripped from the data as its being sent. For example, the 8 bytes of data would be added on every incoming 512 bytes to yield 520 bytes of saved data in memory 38. When sent to disk only 512 bytes will be sent, but the CRC and LBA of those 512 bytes will be checked during the transfer to verify that the data is correct. The check data will provide protection from software bugs, hardware faults and attempted use of invalid data after a power cycle. Data that passes the checks in step 106 and 107 will then be marked as being available for cache read hit operations during the boot process.

After checking integrity of the data, in step 110 the associated usage counter is decremented for each cache slot. As will be seen shortly, the usage counter ensures that only frequently accessed boot data remains in the cache 38.

In step 112, the LIM bit is cleared for all cache slots where the usage counter has been decremented to zero; this then makes that slot available for other boot data, or for use as cache memory during normal post-boot processing.

Once the initialization phase is complete, a step 130 is entered in which it is determined if a data request has been received from the host. If so, then processing will proceed generally as shown on the left hand side of the diagram. If not, and the controller 20 is in an idle period, then processing proceeds to step 150 on the right hand side.

In step 150, if the boot is not in process, then control returns to state 130. If however, a boot is still in progress, then state 152 is entered. Here it is determined if an end of boot sequence has occurred. This can be done by determining if a maximum boot time timer has been exceeded, or a maximum delay time between host requests has been detected. Also, the end of boot sequence processing might be determined by detecting when the maximum number of locked in memory slots have been reached. In any of these events, the boot in process flag is cleared in state 154, and control returns to state 130.

From state 130, if a new host request arrives, state 132 is next executed. Here, a test is made to determine if the disk data (extent) requested by the host is already in the cache memory 38. If so, then state 134 is executed, to increment the usage counter(s) associated with the requested data are incremented. If the requested extent is not already in the cache memory 38, then step 136 is executed to read the extent from the disk into the cache, and to set the CRC field.

In either event, step 140 is executed to determine if a boot is in progress. If no, then the data is sent to the host directly in step 146. If however a boot is in progress, then the LIM flag(s) for the requested extents are set in step 141, prior to returning the data to the host in step 146.

Once the boot initialization phase in steps 100 through 112 is complete and the boot in progress flag has been cleared in step 154, the process of learning and recording boot extents in volatile memory is complete. The process continues in an endless loop processing new host requests at step 130. Such host requests that arrive after boot extents have been locked in memory can benefit from improved performance by sending host data at step 146 from cache memory locked in memory during a previous boot such that the mechanical disk delays in step 136 are avoided. The processing of new host requests continues in this manner until power is cycled on the host computer and the cached boot process begins again at start of boot 100.

In accordance with another aspect of the invention, if there is space available in memory reserved for boot data at the end of the boot process, it will be added to the total available memory for caching, to avoid wastage.

While this invention has been particularly shown and described with references to preferred embodiments thereof, it will be understood by those skilled in the art that various changes in form and details may be made therein without departing from the scope of the invention encompassed by the appended claims.

For example, the disk drive may instead be any sort of mass storage device, including random access memory, a level hierarchy of semiconductor cache memories, a tape drive, etc. The invention will provide an advantage as long as the mass storage device has an access time that is slower than the main memory used by the host system.

The boot process optimizer may be implemented within an input/output controller or host bus adapter through which the host accesses the mass storage device, or even as part of an instruction cache within the host CPU itself.

Because the boot process simply learns the nature of which boot data is needed by detecting actual requests for data from the host to the mass storage device during the boot process, the nature of the data requested is irrelevant to the invention. Therefore, the invention may be implemented in a way that is independent of the host operating system, and may be used to rapidly access both operating system data and application program data during a power on or other boot sequence.

What is claimed is:

1. A data processing system comprising:
a host central processing unit (CPU);
a mass storage device; and
a boot process optimizer, for storing copies of boot data requested from the mass storage device by the host CPU during a boot process, such stored boot data being determined during execution of an initial boot process by the CPU, and such boot data being stored in a nonvolatile cache memory, the non-volatile cache memory having a faster access time than the mass storage device, so that the boot data is available to be read from the cache memory to decrease the execution time of a subsequent boot process, with the boot process optimizer only using predetermined portions of the non-volatile cache memory for storing boot data, so that other regions of the cache memory are available for caching host CPU requests for data from the mass storage device subsequent to the boot processes.

2. An apparatus as in claim 1 wherein the boot data remains in the cache memory after the boot sequence terminates.

3. An apparatus as in claim 1 wherein the boot sequence processing is terminated after a maximum number of cache locations dedicated to storing boot data is reached.

4. An apparatus as in claim 1 wherein the cache memory comprises a plurality of cache slots, each cache slot containing one or more memory locations, and wherein a Locked in Memory (LIM) flag associated with each cache slot is used to determine if the respective slot is presently dedicated for storing boot data.

5. An apparatus as in claim 1 wherein the cache memory comprises a plurality of cache slots, each cache slot containing one or more memory locations, and wherein a usage counter is associated with each cache slot.

6. An apparatus as in claim 1 wherein the usage counter for a cache slot is incremented each time it is accessed during a boot sequence.

7. An apparatus as in claim 1 wherein the usage counters are decremented prior to the execution of a boot sequence, and wherein an associated Locked in Memory (LIM) flag is cleared if the usage counter is decremented to a predetermined value as a result.

8. An apparatus as in claim 1 wherein the boot data stored is determined from parameters of the requests made by the host CPU during the boot process, so that the boot process optimizer is capable of running independently of a host CPU operating system.

9. An apparatus as in claim 9 wherein the boot data is operating system data.

10. An apparatus as in claim 9 wherein the boot data is application program data.

11. An apparatus as in claim 1 wherein the boot process optimizer is implemented in a cache memory controller located in-line between the host CPU and the mass storage device.

12. An apparatus as in claim 1 wherein the boot process optimizer is implemented in an on-drive disk controller.

13. An apparatus as in claim 1 wherein the boot process optimizer is implemented in a cache memory controller located in the host CPU.

14. An apparatus as in claim 14 wherein the cache is an instruction cache.

15. An apparatus as in claim 1 wherein the boot process optimizer is implemented in a host input/output bus adapter.

16. An apparatus as in claim 1 wherein the mass storage device is a disk drive.

17. An apparatus as in claim 1 wherein the mass storage device is a semiconductor memory.

18. An apparatus as in claim 5 wherein any cache slot having its respective LIM flag set is not available for cache replacement during post boot operation.
